(19) United States
(12) Patent Application Publication
(10) Pub. No.: US 2007/0252256 A1
(43) Pub. Date: Nov. 1, 2007

(54) PACKAGE-ON-PACKAGE STRUCTURES

(76) Inventors: Gwang-Man Lim, Seoul (KR); Sang-Ho An, Suwon-si (KR); Young-Hee Song, Seongnam-si (KR)

Correspondence Address: F. CHAU & ASSOCIATES, LLC, 130 WOODBURY ROAD, WOODBURY, NY, 11797, US

(21) Appl. No.: 11/740,363

(22) Filed: Apr. 26, 2007

(30) Foreign Application Priority Data
Apr. 26, 2006 (KR) 2006-37808

(51) Int. Cl. H01L 23/02

(52) U.S. Cl. 257/678

(57) ABSTRACT

A POP (package-on-package) structure includes a first and a second semiconductor chip and a connecting structure. The first semiconductor chip is disposed on a first substrate that includes a plurality of first internal terminals and a plurality of first external terminals. The second semiconductor chip is disposed on a second substrate that includes a plurality of second internal terminals and a plurality of second external terminals. The connecting structure electrically connects at least one of the first external terminals to at least one of the second external terminals.

### CROSS-REFERENCE TO RELATED APPLICATION

This patent application claims priority under 35 U.S.C. § 119 to Korean Patent Application No. 2006-37808, filed on Apr. 26, 2006, the contents of which are herein incorporated by reference in their entirety.

### BACKGROUND OF THE INVENTION

1. Technical Field

The present disclosure relates to a semiconductor package structure and, more particularly, to package-on-package (POP) structures.

2. Discussion of Related Art

Semiconductor device fabrication may include a front-end process in which integrated circuit (IC) chips are formed on a wafer through photolithography, deposition, and etching processes, and a back-end process that assembles and packages each of the IC chips. The assembly and packaging role is expanding to include protecting chips from environmental and handling damage, forming lines on chips for transmitting input/output signals, physically supporting chips and providing heat dissipation in chips.

The proliferation of portable electronic devices is pushing semiconductor packaging technology to meet demands for improved electrical capabilities, reduced cost, lighter weight and slimmer profiles. To satisfy these demands, package on package (POP), chip scale packaging (CSP) and wafer-level packaging (WLP) have been introduced.

FIG. 1 is a cross-sectional view of a conventional POP structure.

Referring to FIG. 1, a first package that includes a first semiconductor chip 15 attached to a first substrate 10 is stacked on a second package that includes a second semiconductor chip 25 attached to a second substrate 20. The first substrate 10 includes first internal terminals 34 and first external terminals 36. The second substrate 20 includes second internal terminals 44 and second external terminals 46. The first internal terminals 34 are electrically connected to the first semiconductor chip 15 through first wires 32, and the second internal terminals 44 are electrically connected to the second semiconductor chip 25 through second wires 42.

External bumps 40, which are connected to the second external terminals 46, are disposed below the second substrate 20. The external bumps 40 are used as electrical connectors for transmitting electrical signals between the first and second semiconductor chips 15 and 25 and an external electronic device (not shown). The second substrate 20 includes an internal interconnection (not shown) that electrically connects the second internal terminals 44 with the second external terminals 46, and includes middle bumps 30 disposed between the first external terminals 36 and the second internal terminals 44 to provide electrical connection between the first external terminals 36 and the second internal terminals 44.

The first and second semiconductor chips 15 and 25 may have different sizes, whereas the first and second substrates 10 and 20 may have the substantially same size. In the case that a small second semiconductor chip 25 is disposed between the first and second substrates 10 and 20, the first and second substrates 10 and 20 are separated from the perimeter of the second semiconductor chip 25. The middle bumps 30 that are disposed in the spaces between the first and second substrates 10 and 20, provide electrical connection between the first external terminals 36 and the second internal terminals 44. The middle bumps 30 can be at least the height of a space (labeled “h” in FIG. 1) between the lower surface of the first substrate 10 and the upper surface of the second substrate 20.

However, it is difficult to reduce the ratio of the size of the middle bumps 30 to the size of the entire package. In the case of package structures having many input/output (I/O) terminals, the size of the middle bumps 30 can result in an increase in the total size of the package.

Part-related warpage may occur in connecting the first package and the second package, which are prepared by different processes. The first and second packages may deform differently under subsequent processes due to various factors such as thermal stress, and this difference in deformation between the first and second packages results in warpage. However, conventional methods are insufficient to avoid warpage in structures in which the first and second packages are connected by using the middle bumps 30.

### SUMMARY OF THE INVENTION

In an exemplary embodiment of the present invention, a package-on-package (POP) structure includes a first semiconductor chip disposed on a first substrate including a plurality of first internal terminals and a plurality of first external terminals; a second semiconductor chip disposed on a second substrate including a plurality of second internal terminals and a plurality of second external terminals and a connecting structure electrically connecting at least one of the first external terminals to at least one of the second external terminals.

In an exemplary embodiment of the present invention, a POP structure includes a first bonding member connecting the first semiconductor chip to the first internal terminals of the first substrate, and a second bonding member connecting the second semiconductor chip to the second internal terminals of the second substrate. The first and the second bonding members may be a wire bonding structure or a solder bump structure. The connecting structure may include wires directly connecting the first external terminals to the second external terminals, and a protective layer pattern disposed between the first substrate and the second substrate and encapsulating the wires.

The first substrate may include a first interconnection structure electrically connecting the first internal terminals with the first external terminals, and the second substrate may include a second interconnection structure electrically connecting the second internal terminals with the second external terminals.

In an exemplary embodiment of the present invention, a POP structure may include external bump pads coupled to at least one of the first external terminals that is not connected to the connecting structure, and internal bump pads coupled to at least one of the second external terminals that is not connected to the connecting structure. The external bump pads may have a thickness of about 80% to about 120% of a thickness of the internal bump pads.

The first interconnection structure may include at least one first internal interconnection connecting the first internal terminals to the external bump pads, second internal interconnections connecting at least one of the first external terminals that is connected to the connecting structure to at least one of the first external terminals that is not connected to the connecting structure, and third internal interconnections connecting at least one of the first external terminals that is connected to the connecting structure to the first internal terminals and at least one of the first external terminals that is not connected to the connecting structure.

The second interconnection structure may include at least one fourth internal interconnection connecting the second internal terminals to the internal bump pads, fifth internal interconnections connecting at least one of the second external terminals that is connected to the connecting structure to at least one of the second external terminals that is not connected to the connecting structure, and sixth internal interconnections connecting at least one of the second external terminals that is connected to the connecting structure to the second internal terminals and to at least one of the second external terminals that is not connected to the connecting structure.

In an exemplary embodiment of the present invention, a POP structure may include internal bump pads coupled to at least one of the second external terminals that is not connected to the connecting structure, wherein the first external terminals may all be connected to at least one of the second external terminals through the connecting structure.

The first substrate may have a greater surface area than the second substrate, and the first substrate may include a concaved lower surface with a circumvallation part defining a predetermined recessed region. The second substrate may be coupled to the recessed region of the first substrate through an adhering member. The circumvallation part may have a thickness of about 50% to about 100% of a distance between a lower surface of the second substrate and a lower surface of the recessed region.

In an exemplary embodiment of the present invention, a POP structure may include at least one middle substrate disposed between the first substrate and the second substrate, and including middle internal terminals and middle external terminals, and a middle semiconductor chip coupled to the middle substrate, wherein at least one of the middle external terminals may be electrically connected to at least one of the first external terminals and the second external terminals.

### BRIEF DESCRIPTION OF THE FIGURES

The present invention will become readily apparent to those of ordinary skill in the art when descriptions of exemplary embodiments thereof are read with reference to the accompanying drawings.

FIG. 1 is a cross-sectional view of a conventional POP structure.

FIGS. 2 and 3 are cross-sectional views of POP structures according to exemplary embodiments of the present invention.

FIG. 4 is a cross-sectional view showing an interconnection structure of a substrate according to an exemplary embodiment of the present invention.

FIGS. 5 through 8 are cross-sectional views of POP structures according to exemplary embodiments of the present invention.

FIG. 9 is a perspective view of a POP structure according to an exemplary embodiment of the present invention.

FIGS. 10 through 12 are cross-sectional views of package structures employing flip-chip technology according to exemplary embodiments of the present invention.

### DESCRIPTION OF EXEMPLARY EMBODIMENTS

Hereinafter, exemplary embodiments of the present invention will be described in detail with reference to the accompanying drawings. In the drawings, the sizes and thicknesses of layers and regions may be exaggerated for clarity.

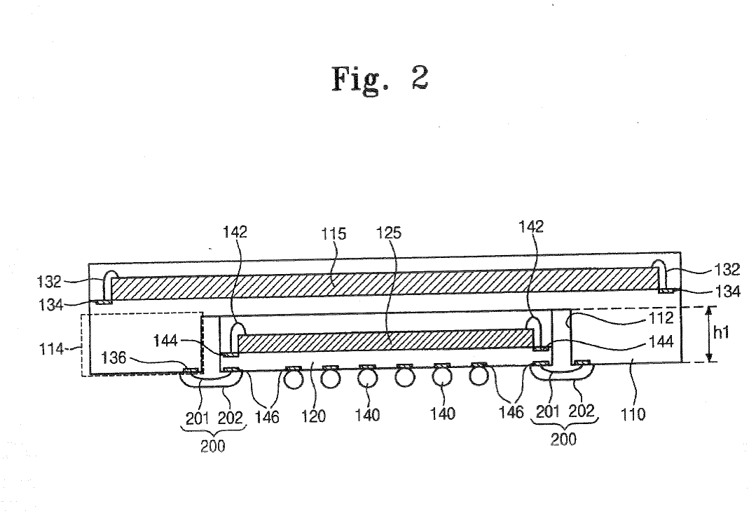

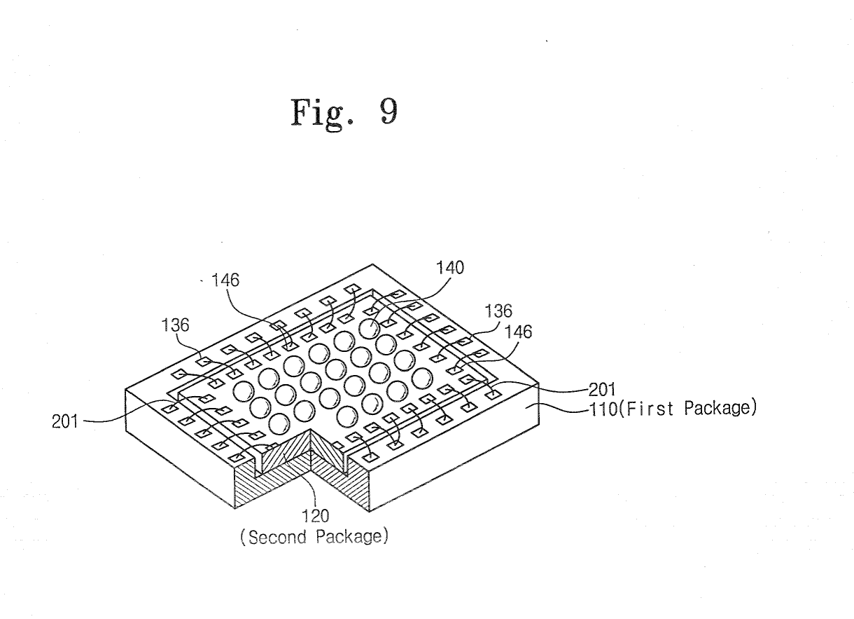

FIGS. 2 and 9 are cross-sectional views of POP structures according to exemplary embodiments of the present invention.

Referring to FIGS. 2 and 9, a POP structure according to an exemplary embodiment of the present invention includes a first package stacked on a second package. The first package includes a first semiconductor chip 115 coupled to a first substrate 110, and the second package includes a second semiconductor chip 125 coupled to a second substrate 120. The first semiconductor chip 115 may have a surface area larger than that of the second semiconductor chip 125. For example, the first semiconductor chip 115 may be a memory chip, and the second semiconductor chip 125 may be a large scale integration (LSI) chip. However, it is to be understood that the first semiconductor chip 115 and the second semiconductor chip 125 may be embodied using various types of chips.

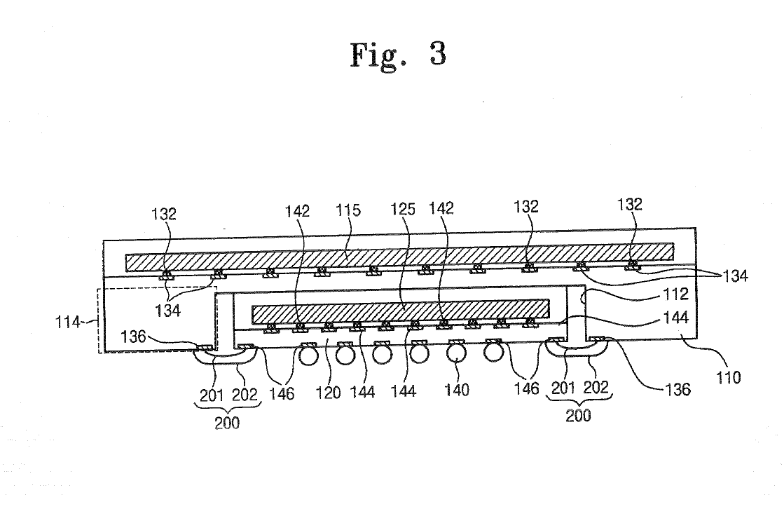

An upper region of the first substrate 110 includes first internal terminals 134 disposed thereon, and a lower region includes first external terminals 136 disposed thereon, as shown in FIGS. 2 and 3. An upper region of the second substrate 120 includes second internal terminals 144 disposed thereon, and a lower region includes second external terminals 146 disposed thereon.

As shown in FIGS. 2, 3, 5, 6 and 7, the first internal terminals 134 are connected to the first semiconductor chip 115 through a first bonding member 132, and the second internal terminals 144 are connected to the second semiconductor chip 125 through a second bonding member 142. The first and second bonding members 132 and 142 may be wire bonding structures or solder bump structures. The first and second bonding members 132 and 142 may be wires formed of a conductive material such as gold. The first and second semiconductor chips 115 and 125 may be electrically connected to the first and second substrates 110 and 120 through solder bumps 132 and 142, as shown in FIG. 3.

According to an exemplary embodiment of the present invention, the lower surface of the first substrate 110 includes a circumvallation part 114 formed thereon that defines a recessed region 112, wherein the first substrate 110 is thinner at the recessed region 112 than at the circumvallation part 114. For example, the first substrate 110 is formed as a concaved structure. The second package may use a member (not shown) to attach to the bottom surface of the recessed region 112. To reduce the discrepancy in the height between the first substrate 110 and the second substrate 120, the circumvallation part 114 may have a thickness that is about 50% to about 100% of that of the second package. According to an exemplary embodiment of the present invention, the substrate height reduction due to the circumvallation part eliminates the need for a middle bump, and warpage may be avoided and an increase in size of the overall package can be prevented.

The first substrate 110 may include a first interconnection structure for connecting the first internal terminals 134 to the first external terminals 136, and the second substrate 120 may include a second interconnection structure for connecting the second internal terminals 144 to the second external terminals 146. The first external terminals 136 may use a connecting structure 200 to directly connect to the second external terminals 146. The connecting structure 200 may include wires 201 connecting the first external terminals 136 to the corresponding second external terminals 146 and may include a protective layer pattern 202 encapsulating the wires 201. The wires 201 may be formed using conventional wire bonding techniques. The protective layer pattern 202 may be disposed between the first substrate 110 and the second substrate 120, for example, to protect the wires 201 from physical and chemical damage. The protective layer pattern 202 may be formed of an epoxy material and may fill the recessed region 112 in which the second package is disposed.

In an exemplary embodiment of the present invention, the first substrate 110 and the second substrate 120 are electrically connected through the wires 201, and the first and second packages can be protected from warpage even when the positions of the lower surfaces of the first substrate 110 and the second substrate 120 are different, and the bonding process may not be restricted due to the wires 201.

In an exemplary embodiment of the present invention, all of the first external terminals 136 are connected to the connecting structure 200, and the connecting structure 200 is connected to a set of the second external terminals 146. The internal bumps 140 shown in FIGS. 2 and 3 are disposed at the bottoms of the second external terminals 146 and are not connected to the connecting structure 200. The internal bumps 140 may be used as electrical connectors for transferring electrical signals between the first and second semiconductor chips 115 and 125 and an external electronic device (not shown).

In an exemplary embodiment of the present invention, the internal bumps 140 are electrically connected to the first and second semiconductor chips 115 and 125 through the first and second interconnections and the connecting structure 200. For example, all of the first internal terminals 134 may be electrically connected to the first external terminals 136 through the first interconnection structure, and the second internal terminals 144 may be electrically connected to the second external terminals 146 through the second interconnection structure. When all of the first external terminals 136 are electrically connected to the second external terminals 146 through the connecting structure 200, all of the first internal terminals 134 may also be electrically connected to the second external terminals 146.

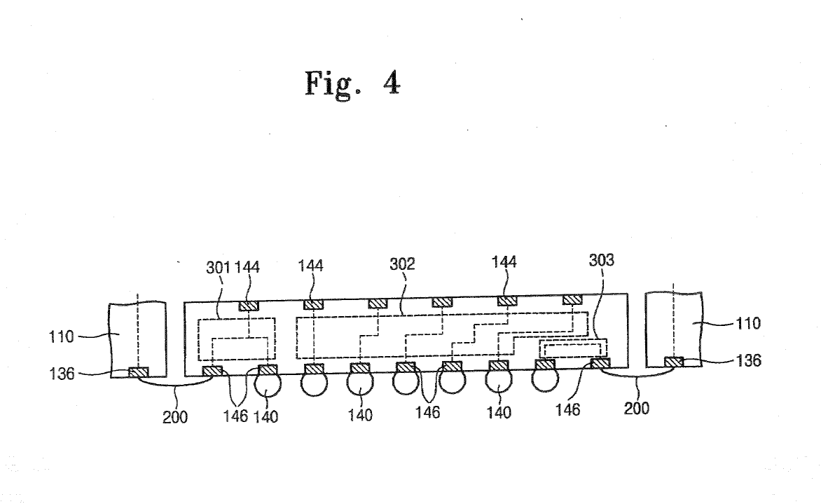

In an exemplary embodiment of the present invention, at least one of the second internal terminals 144 is connected to the connecting structure 200 (as shown in dashed block 301 of FIG. 4), and at least one of the second internal terminals 144 is not connected to the connecting structure 200. A connecting structure 200 that is not connected to at least one of the second internal terminals 144 may be connected to at least one of the internal bumps 140 through the second interconnection structure (as shown in dashed block 302 of FIG. 4). In an exemplary embodiment of the present invention, the first internal terminals 134 are connected to the internal bumps 140 through the first and second interconnection structures and the connecting structure 200, and at least one of the first internal terminals 134 is connected to the second internal terminals 144, and at least one of the first internal terminals 134 that is not connected to the second internal terminals 144 is connected to the internal bumps 140 (as shown in dashed block 303 of FIG. 4).

It is to be understood that the first interconnection structure may be formed differently than that shown in FIG. 4. In an exemplary embodiment of the present invention, the first substrate 110 does not have the internal bumps 140, and includes interconnections connecting the first internal terminals 134 and the first external terminals 136.

A package structure according to an exemplary embodiment of the present invention uses the connecting structure 200 and the second interconnection structure to connect the first and second semiconductor chips 115 and 125 to the internal bumps 140, such that the number of bumps for connecting to an external electronic device may be reduced. As shown by dashed block 301 in FIG. 4, one of the first internal terminals 134 is electrically connected within the second interconnection structure, such that one of the internal bumps 140 may be shared by the first and second semiconductor chips 115 and 125, and the number of internal bumps may be reduced. According to an exemplary embodiment of the present invention, a number of the ground terminals, power terminals, and signal terminals of the first and second semiconductor chips 115 and 125 may be connected to the shared internal bumps.

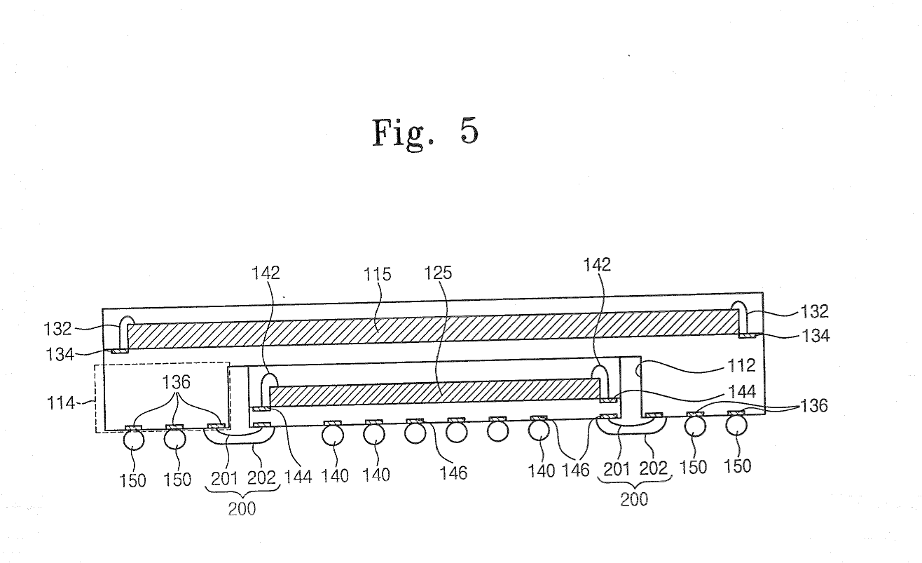

FIG. 5 is a cross-sectional view of a POP package structure according to an exemplary embodiment of the present invention. The POP package structure of FIG. 5 is similar to that described in connection with FIGS. 2 and 3, except for the allocations of the first and second interconnection structures and the bumps. Accordingly, further descriptions of the common elements will be omitted in the interests of brevity.

Referring to FIG. 5, a portion of the first external terminals 136 is connected to the second external terminals 146 through the connecting structure 200; however, the remaining portion of the first external terminals 136 is connected to an external electronic device through separate bumps 150 coupled to the lower surface of the first substrate 110. That is, the first interconnection structure and the second interconnection structure in this embodiment have been altered from those of previous embodiments.

The first interconnection structure may each include a first internal interconnection connected to the external bumps 150, a second internal interconnection connected to the connecting structure 200, and a third internal interconnection commonly connected to the external bumps 150 and the connecting structure 200. The second interconnection structure may include a structure with fourth through sixth internal interconnections that correspond to the first through third internal interconnections of the first interconnection structure. In an exemplary embodiment of the present invention, the third through sixth internal interconnections have a connecting structure, such as that shown in dashed block 301 of FIG. 4, that allows sharing of internal or external bumps 150, and the number of bumps can be reduced.

According to an exemplary embodiment of the present invention, the connecting structure including the wires 201 connects the first and second packages, and warpage may be avoided. When the first substrate 110 includes the circumvallation part 114, according to an exemplary embodiment of the present invention, the middle bumps can be eliminated and warpage may be avoided and increased overall package size may be prevented.

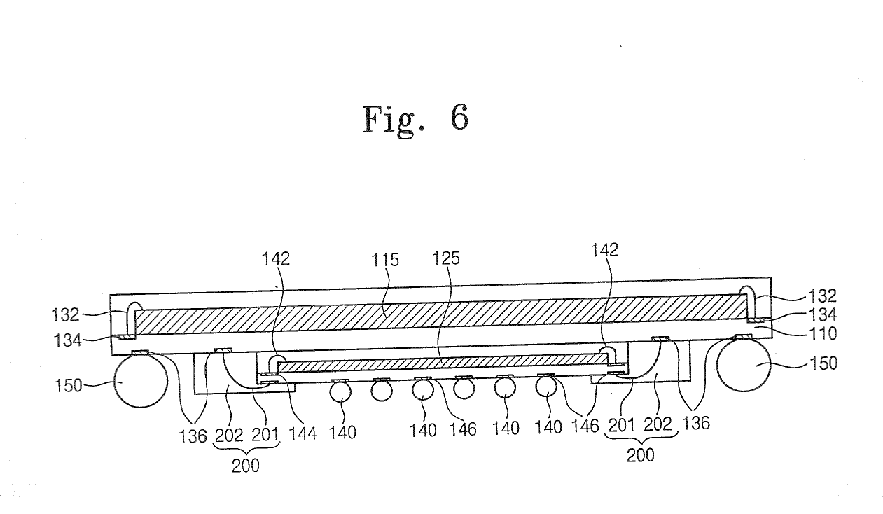

FIG. 6 is a cross-sectional view of a POP package structure according to an exemplary embodiment of the present invention. The POP package structure of FIG. 6 is similar to that of an exemplary embodiment described in connection with FIG. 5 except that the first substrate 110 has a flat bottom surface. Further descriptions of the common elements will be omitted in the interests of brevity.

Referring to FIG. 6, the first substrate 110 includes a planarized lower surface on which first external terminals 136 are disposed. At least one of the first external terminals 136 is electrically connected through the connecting structure 200, for example, the wires 201, to the second external terminals 146 of the second substrate 120. Providing this electrical connection through the connecting structure 200 may avoid the warpage caused by deformation of the first and second packages. The lower portions of the first external terminals 136 that are not connected through the connecting structure 200 are coupled to the external bumps 150.

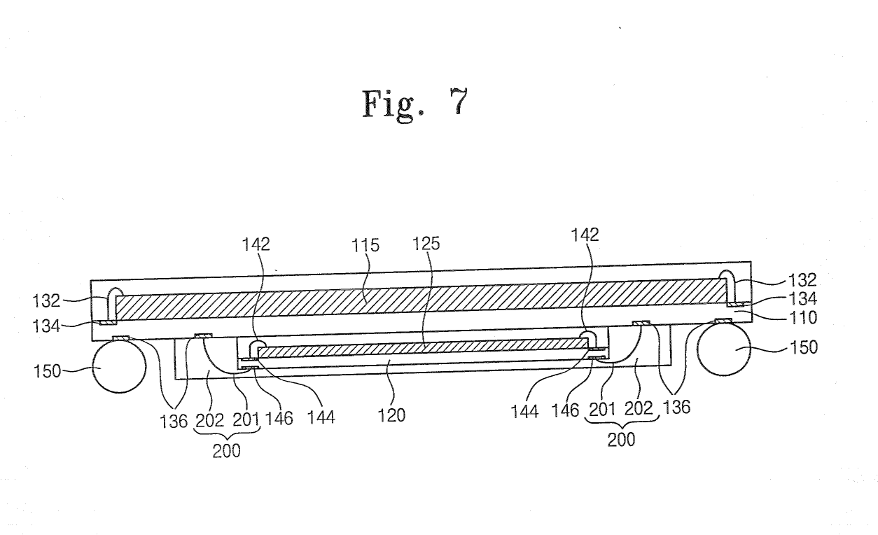

FIG. 7 is a cross-sectional view of a POP package structure according to an exemplary embodiment of the present invention. The POP package structure of FIG. 7 is similar to a POP structure according to an exemplary embodiments of the present invention described in connection with FIGS. 2 through 6, except that internal bumps 140 are not included on the second substrate 120.

Referring to FIG. 7, the first and second semiconductor substrates 115 and 125 may be connected to an external electronic device (not shown) through external bumps 150 disposed at the bottom of the first substrate 110. The first and second interconnection structures and the connecting structure 200 for these electronic connections may be different from those in exemplary embodiments described in connection with FIGS. 2 through 6.

As shown in FIG. 7 the first package and the second package are electrically connected through the wires 201, and the first and second packages may be unsusceptible to warpage through deformation.

For providing a secure connection with an external electronic device, the lower surfaces of the external bumps 150 and the internal bumps 140 may be even, as shown FIGS. 5 and 6.

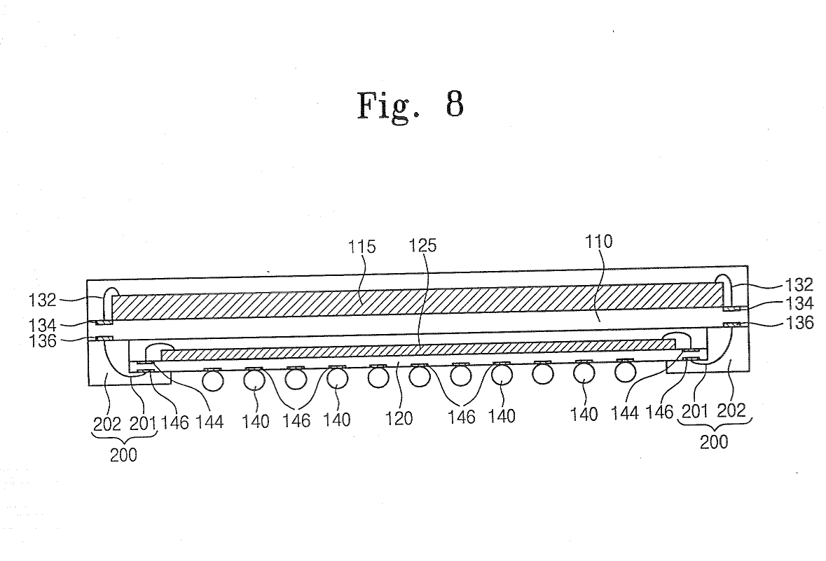

FIG. 8 is a cross-sectional view of a POP package structure according to an exemplary embodiment of the present invention. The POP package structure of FIG. 8 is similar to a POP structure according to an exemplary embodiment of the present invention described in connection with FIGS. 2 and 3, except there is no circumvallation part 114.

Referring to FIG. 8, the bottom surface of the first substrate 110, which may be planarized, includes first external terminals 136 disposed thereon. The first and second substrates 110 and 120 are electrically connected through the connecting structure 200, and all the first external terminals 136 of the first substrate 110 are connected to the second external terminals 146 through the connecting structure 200.

As shown in FIG. 8, there is no circumvallation part 114, and the wires 201 connect the first external terminals 136 and the second external terminals 146 that are on different levels, which may be useful when there is little size discrepancy between the first and second packages. For example, a POP package structure according to an exemplary embodiment of the present invention described in connection with FIG. 8 may be useful for the case when the size of the first semiconductor chip 115 is between about 1.1 to about 1.5 times the size of the second semiconductor chip 125.

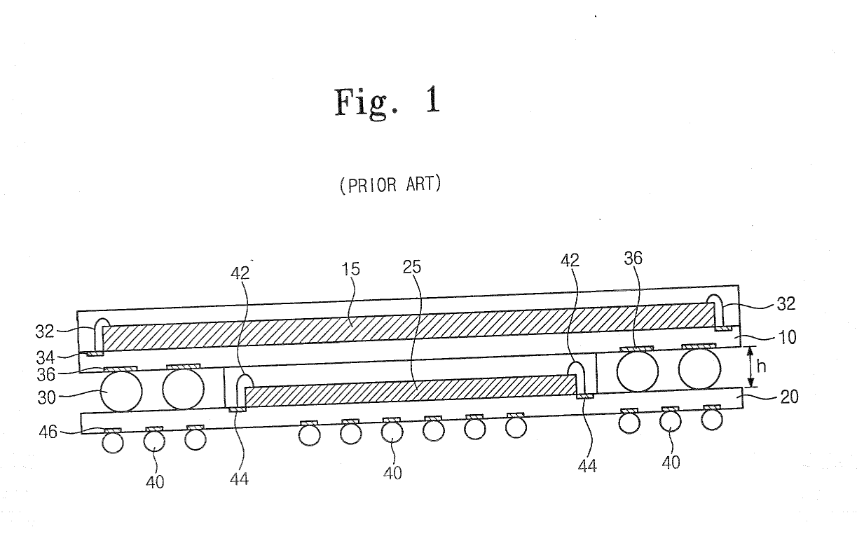

At least one middle package may be disposed between the first package and the second package. The middle package may electrically connect the first and second packages. For example, this electrical connection may be formed similar to the substrate and interconnection structures described in connection with FIGS. 1 through 5.

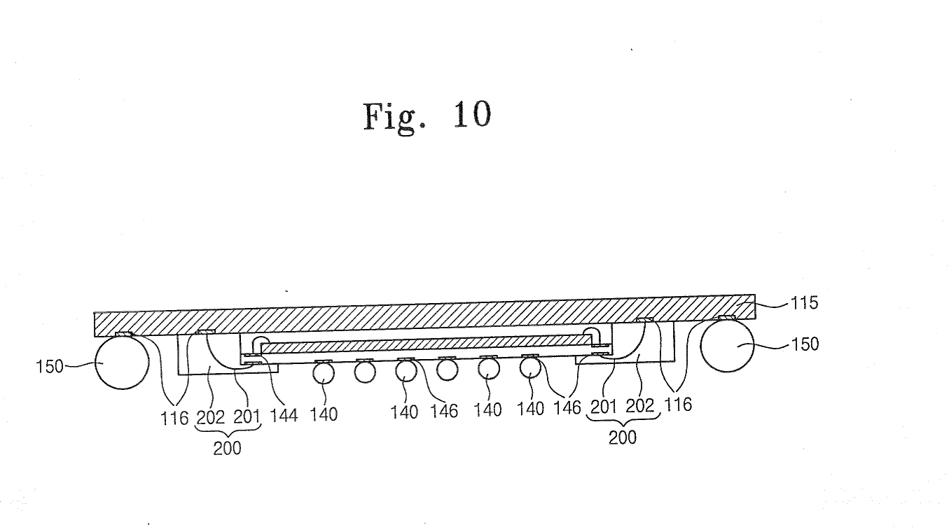

The plurality of manufactured semiconductor chips may be packaged using a flip-chip method. In a flip-chip method, bumps for connecting to an external electronic device are formed on the top of a semiconductor chip itself. A package structure employing a flip-chip method according to an exemplary embodiment of the present invention will be described with reference to FIGS. 10 through 12.

Referring to FIG. 10, the first package may be a first semiconductor chip 115 including first input/output terminals 116 and external bumps 150. In this case, the first semiconductor chip 115 may be formed in a flip-chip structure. The second package includes a second substrate 120, which includes second internal terminals 144 and second external terminals 146, and a second semiconductor chip 125 disposed above the second substrate 120. For example, the second package of FIG. 10 may be a substrate-based package structure.

At least one of the first input/output terminals 116 of the first semiconductor chip 115 is electrically connected to the second external terminals 146 of the second package through the connecting structure 200. The connecting structure 200 and the second package of FIG. 10 may be the same as those of exemplary embodiments of the present invention described in connection with FIGS. 2 through 9. At least one of the first input/output terminals 116 that is not connected to the connecting structure 200 is connected to an external electronic device (not shown) through external bumps 150 disposed below the first semiconductor chip 115 as shown in FIG. 10.

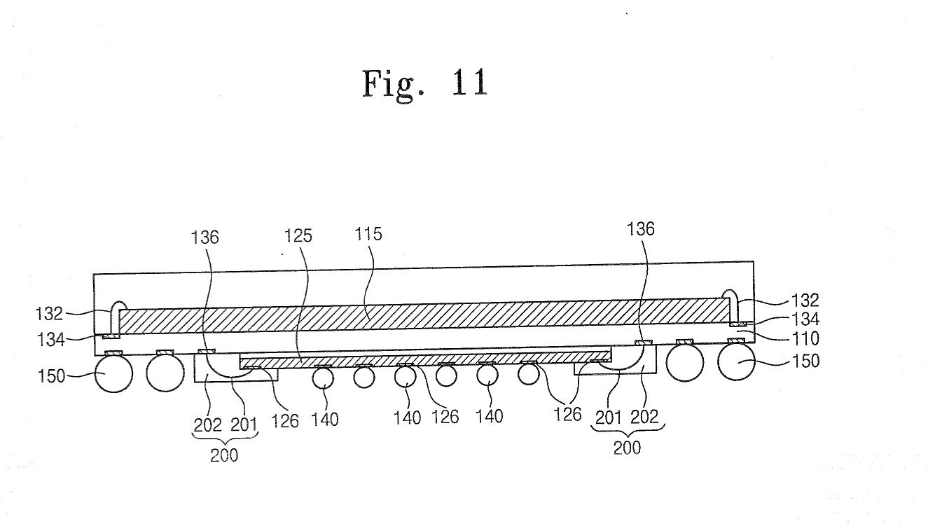

Referring to FIG. 11, the second package may be a second semiconductor chip 125 having second input/output terminals 126 and internal bumps 140. The second semiconductor chip 125 may be formed in a flip-chip structure. The first package includes a first substrate 110, which includes first internal terminals 134 and first external terminals 136, and a first semiconductor chip 115 disposed above the first substrate 110. For example, the first package may be a substrate-based package structure.

A portion of the second input/output terminals 126 of the second semiconductor chip 125 is electrically connected to the first external terminals 136 of the first package through the connecting structure 200. The connecting structure 200 and the first package of FIG. 10 may be the same as those of exemplary embodiments of the present invention described in connection with FIGS. 2 through 9. At least one of the second input/output terminals 126 that is not connected to the connecting structure 200 may be connected to an external electronic device (not shown) through the internal bumps 140 disposed below the second semiconductor chip 125 as shown in FIG. 11.

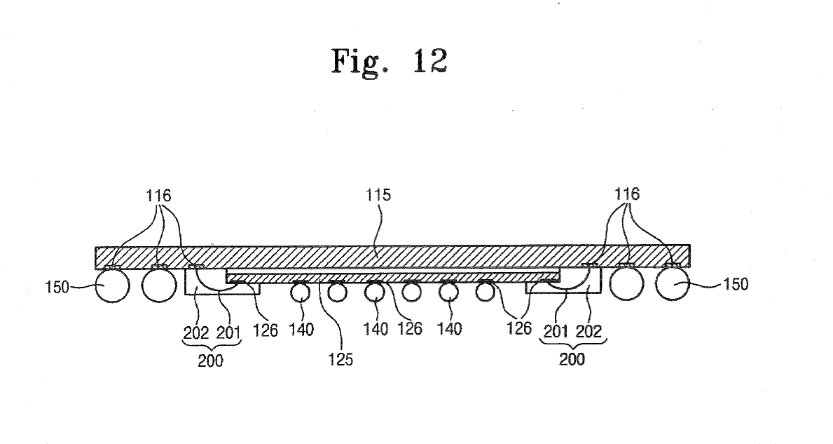

Referring to FIG. 12, the first package may be a first semiconductor chip 115 including first input/output terminals 116 and external bumps 150, and the second package may be a second semiconductor chip 125 including second input/output terminals 126 and internal bumps 140. The first and second semiconductor chips 115 and 125 may be formed in flip-chip structures.

At least one of the second input/output terminals 126 of the second semiconductor chip 125 is electrically connected to at least one corresponding one of the first input/output terminals 116 of the first semiconductor chip 115 through the connecting structure 200. The connecting structure 200 of FIG. 12 may be the same as a connecting structure 200 described in connection with FIGS. 2 through 9. At least one of the first and second input/output terminals 116 and 126 that is not connected to the connecting structure 200 is connected to an external electronic device (not shown) through the internal and external bumps 140 and 150, which are disposed below the second and first packages, respectively, as shown in FIG. 12. The external bumps 150 may have a thickness of about 80% to about 120% of a thickness of the internal bumps 140.

The first and second packages according to exemplary embodiments of the present invention are electrically connected through wires such that they become packages that are not prone to warpage and may require a lesser number of bumps for connecting to an external electronic device.

According to exemplary embodiments of the present invention, a circumvallation part is disposed on the bottom surface of the first substrate to reduce the discrepancy in the height between the lower surfaces of the first and second substrates and separate bumps are not required between the first and second substrates, and warpage may be avoided and an overall size increase of the package can be prevented.

Although the exemplary embodiments of the present invention have been described in detail with reference to the accompanying drawings for the purpose of illustration, it is to be understood that inventive processes and apparatus should not be construed as limited thereby. It will be readily apparent to those of ordinary skill in the art that various modifications to the foregoing exemplary embodiments can be made without departing from the scope of the present invention as defined by the appended claims, with equivalents of the claims to be included therein.

What is claimed is:

1. A POP (package-on-package) structure comprising:
a first semiconductor chip disposed on a first substrate including a plurality of first internal terminals and a plurality of first external terminals;
a second semiconductor chip disposed on a second substrate including a plurality of second internal terminals and a plurality of second external terminals; and
a connecting structure electrically connecting at least one of the first external terminals to at least one of the second external terminals.

2. The POP structure of claim 1, further comprising: a first bonding member connecting the first semiconductor chip to the first internal terminals of the first substrate and a second bonding member connecting the second semiconductor chip to the second internal terminals of the second substrate,
wherein the first bonding member is one of a wire bonding structure and a solder bump structure, and wherein the second bonding member is one of a wire bonding structure and a solder bump structure.

3. The POP structure of claim 1, wherein the connecting structure comprises:
wires directly connecting the first external terminals to the second external terminals; and
a protective layer disposed between the first substrate and the second substrate and encapsulating the wires.

4. The POP structure of claim 1, wherein
the first substrate includes a first interconnection structure electrically connecting the first internal terminals with the first external terminals, and
the second substrate includes a second interconnection structure electrically connecting the second internal terminals with the second external terminals.

5. The POP structure of claim 4, further comprising:
a plurality of external bump pads, wherein at least one of the external bump pads is coupled to a corresponding one of the first external terminals that is not connected to the connecting structure; and
a plurality of internal bump pads, wherein at least one of the internal bump pads is coupled to a corresponding one of the second external terminals that is not connected to the connecting structure.

6. The POP structure of claim 5, wherein the first interconnection structure comprises:
at least one first internal interconnection connecting at least one of the first internal terminals to a corresponding one of the external bump pads;
second internal interconnections connecting at least one of the first external terminals that is connected to the connecting structure to at least of the first external terminals that is not connected to the connecting structure; and
third internal interconnections connecting at least one of the first external terminals that is connected to the connecting structure to at least one of the first internal terminals and at least one of the first external terminals not connected to the connecting structure.

7. The POP structure of claim 5, wherein the second interconnection structure comprises:
at least one fourth internal interconnection connecting at least one of the second internal terminals to at least one of the internal bump pads;
fifth internal interconnections connecting at least one of the second external terminals that is connected to the connecting structure to at least one of the second external terminals that is not connected to the connecting structure; and
sixth internal interconnections connecting at least one of the second external terminals that is connected to the connecting structure to the second internal terminals and connecting at least one of the second external terminals that is not connected to the connecting structure.

8. The POP structure of claim 4, wherein the first external terminals are connected to corresponding ones of the second external terminals through the connecting structure, and wherein the POP structure further comprises internal bump pads coupled to the second external terminals that are not connected to the connecting structure.

9. The POP structure of claim 8, wherein the second interconnection structure comprises:
at least one fourth internal interconnection connecting the second internal terminals to the internal bump pads;
fifth internal interconnections connecting at least one of the second external terminals that is connected to the connecting structure to at least one of the second external terminals that is not connected to the connecting structure; and
sixth internal interconnections connecting at least one of the second external terminals that is connected to the connecting structure to at least one of the second external terminals and at least one of the second external terminals that is not connected to the connecting structure.

10. The POP structure of claim 1, wherein
the first substrate has a greater area than the second substrate,
a lower portion of the first substrate is formed concavely such that the first substrate has a circumvallation part defining a predetermined recessed region,
the second substrate is coupled to the recessed region of the first substrate through a predetermined adhering member, and
the circumvallation part has a thickness of about 50% to about 100% of a distance from a lower surface of the second substrate to a lower surface of the recessed region.

11. The POP structure of claim 1, further comprising:
at least one middle substrate disposed between the first substrate and the second substrate, and including middle internal terminals and middle external terminals; and
a middle semiconductor chip coupled to the middle substrate,
wherein at least one of the middle external terminals is electrically connected to at least one of the first external terminals and the second external terminals.

12. A POP structure comprising:
a first substrate comprising first internal terminals, first external terminals and a circumvallation part defining a predetermined recessed region;
a first semiconductor chip disposed on the first substrate;
a second substrate disposed in the recessed region of the first substrate and including second internal terminals and second external terminals;
a second semiconductor chip disposed between the first substrate and the second substrate;
a connecting structure electrically connecting at least one of the first external terminals to at least one of the second external terminals; and
internal bump pads coupled to corresponding second external terminals that are not connected to the connecting structure.

13. The POP structure of claim 12, wherein
the first substrate includes a first interconnection structure electrically connecting the first internal terminals to the first external terminals, and
the second substrate includes a second interconnection structure electrically connecting the second internal terminals to the second external terminals.

14. The POP structure of claim 13, wherein the first external terminals are connected to corresponding second external terminals through the connecting structure.

15. The POP structure of claim 13, wherein at least one of the first external terminals is connected to at least one of the second external terminals through the connecting structure, and wherein the POP structure further comprises external bump pads coupled to corresponding first external terminals that are not connected to the connecting structure.

16. The POP structure of claim 15, wherein the first interconnection structure comprises:
at least one first internal interconnection connecting the first internal terminals to the external pump pads;
at least one second internal interconnection connecting at least one of the first external terminals that is connected to the connecting structure to at least one of the first external terminals that is not connected to the connecting structure; and
at least one third internal interconnection connecting at least one of the first external terminals that is connected to the connecting structure to the first internal terminals and at least one of the first external terminals that is not connected to the connecting structure.

17. The POP structure of claim 13, wherein the second interconnection structure comprises:
at least one fourth internal interconnection connecting the second internal terminals to the internal bump pads;
at least one fifth internal interconnection connecting at least one of the second external terminals that is connected to the connecting structure to at least one of the second external terminals that is not connected to the connecting structure; and
at least one sixth internal interconnection connecting at least one of the second external terminals that is connected to the connecting structure to the second internal terminals and at least one of the second external terminals that is not connected to the connecting structure.

18. The POP structure of claim 15, wherein the external bump pads have a thickness of about 80% to about 120% of a thickness of the internal bump pads.

19. A POP structure comprising:
a first package including a plurality of first input/output terminals;
a second package including a plurality of second input/output terminals; and
a connecting structure electrically connecting at least one of the first input/output terminals to at least one of the second input/output terminals.

20. The POP structure of claim 19, wherein
the first package includes a first semiconductor chip and the second package includes a second semiconductor chip,
the first package is a flip-chip package structure including the first input/output terminals disposed on the first semiconductor chip or a substrate-based package structure including the first semiconductor chip disposed on the first substrate with the first internal terminals and the first external terminals, and
the second package is a flip-chip package structure including the second input/output terminals disposed on the second semiconductor chip or a substrate-based package structure including the second semiconductor chip disposed on the second substrate with the second internal terminals and the second external terminals.

21. The POP structure of claim 19, wherein the connecting structure comprises:
a wire directly connecting at least one of the first input/output terminals to at least one of the second input/output terminals; and
a protective layer pattern encapsulating the wire.

22. The POP structure of claim 19, further comprising bumps for connecting with an external electronic device, wherein at least one of the bumps is coupled to at least one of the first input/output terminals that is not connected to the connecting structure.
